(19) United States
(12) Patent Application Publication
(10) Pub. No.: US 2023/0326914 A1
(43) Pub. Date: Oct. 12, 2023

(54) SENSING DEVICE

(71) Applicant: AUO Corporation, Hsinchu (TW)

(72) Inventors: Shuo-Hong Wang, Hsinchu (TW); Yang-En Wu, Hsinchu (TW); Chao-Chien Chiu, Hsinchu (TW)

(73) Assignee: AUO Corporation, Hsinchu (TW)

(21) Appl. No.: 17/950,069

(22) Filed: Sep. 21, 2022

(30) Foreign Application Priority Data
Apr. 7, 2022 (TW) 111113191

(51) Int. Cl. H01L 25/16; G06V 40/13; H01L 51/42; H01L 33/62

(52) U.S. Cl. CPC H01L 25/167; G06V 40/1318; H01L 51/42; H01L 33/62

(57) ABSTRACT

A sensing device, including a first substrate, a first sensing element, a light-emitting element, and a light-shielding layer, is provided. The first sensing element is located on the first substrate. The light-emitting element is located on the first sensing element. The light-shielding layer is located between the light-emitting element and the first sensing element, and is electrically connected to the light-emitting element.

### CROSS-REFERENCE TO RELATED APPLICATION

This application claims the priority benefit of Taiwan application serial no. 111113191, filed on Apr. 7, 2022. The entirety of the above-mentioned patent application is hereby incorporated by reference herein and made a part of this specification.

### BACKGROUND

### Technical Field

The disclosure relates to an optoelectronic device, and more particularly to a sensing device.

### Description of Related Art

In order to provide the information required to construct a smart living environment, various sensors have been widely used in daily life. For example, a mobile phone may be equipped with a sensing element having a fingerprint recognition function for unlocking. Since ridges and valleys of a fingerprint can generate reflected light with different intensities, the sensing element can generate currents with different magnitudes by detecting light rays reflected by the fingerprint of a finger, thereby distinguishing the shape of the fingerprint. In other words, a fingerprint sensing element needs to cooperate with a light source for sensing. However, how to simplify the integrated structure of the light source and the sensing element is still one of the goals that the industry seeks to improve.

### SUMMARY

The disclosure provides a sensing device, which has a simplified integrated structure.

An embodiment of the disclosure provides a sensing device, which includes a first substrate; a first sensing element, located on the first substrate; a light-emitting element, located on the first sensing element; and a light-shielding layer, located between the light-emitting element and the first sensing element, and electrically connected to the light-emitting element.

In an embodiment of the disclosure, an orthographic projection of the first sensing element on the first substrate at least partially overlaps with an orthographic projection of the light-emitting element on the first substrate.

In an embodiment of the disclosure, the light-emitting element emits visible light, and the visible light includes at least two color lights.

In an embodiment of the disclosure, the light-emitting element emits invisible light.

In an embodiment of the disclosure, the sensing device further includes a light angle control layer, located between the light-shielding layer and the light-emitting element, and the light-shielding layer and the light angle control layer are respectively electrically connected to two pads of the light-emitting element.

In an embodiment of the disclosure, the sensing device further includes a second sensing element, located between the light-shielding layer and the light-emitting element.

In an embodiment of the disclosure, an electrode of the second sensing element is electrically connected to the light-emitting element.

In an embodiment of the disclosure, an orthographic projection of the second sensing element on the first substrate at least partially overlaps with an orthographic projection of the first sensing element on the first substrate.

In an embodiment of the disclosure, an orthographic projection of the second sensing element on the first substrate is outside an orthographic projection of the first sensing element on the first substrate.

In an embodiment of the disclosure, the sensing device further includes a second sensing element, and the first sensing element and the second sensing element are located on different sides of the light-emitting element.

In an embodiment of the disclosure, an orthographic projection of the second sensing element on the first substrate is outside an orthographic projection of the light-emitting element on the first substrate.

In an embodiment of the disclosure, the second sensing element is an organic photodiode.

In an embodiment of the disclosure, the first sensing element is a fingerprint sensing element.

In order for the features and advantages of the disclosure to be more comprehensible, the following specific embodiments are described in detail in conjunction with the drawings.

### BRIEF DESCRIPTION OF THE DRAWINGS

FIG. 1A is a schematic partial top view of a sensing device 10 according to an embodiment of the disclosure.

FIG. 1B is a schematic cross-sectional view taken along a cross-sectional line A-A′ of

FIG. 1A.

FIG. 2 is a schematic partial top view of a sensing device 20 according to an embodiment of the disclosure.

FIG. 3A is a schematic partial top view of a sensing device 30 according to an embodiment of the disclosure.

FIG. 3B is a schematic cross-sectional view taken along a cross-sectional line B-B′ of FIG. 3A.

FIG. 4 is a schematic partial cross-sectional view of a sensing device 40 according to an embodiment of the disclosure.

FIG. 5A is a schematic partial top view of a sensing device 50 according to an embodiment of the disclosure.

FIG. 5B is a schematic cross-sectional view taken along a cross-sectional line C-C′ of FIG. 5A.

### DETAILED DESCRIPTION OF DISCLOSED EMBODIMENTS

In the drawings, the thickness of layers, films, panels, regions, etc., is exaggerated for clarity. Throughout the specification, the same reference numerals represent the same elements. It should be understood that when an element such as a layer, a film, a region, or a substrate is referred to as being “on” another element or “connected to” another element, the element may be directly on the another element or connected to the another element, or there may be an intermediate element. In contrast, when an element is referred to as being “directly on” another element or “directly connected to” another element, there is no intermediate element. As used herein, “connection” may refer to physical and/or electrical connection. Furthermore, “electrical connection” or “coupling” may be that there is another element between two elements.

It should be understood that although terms such as “first”, “second”, and “third” may be used herein to describe various elements, components, regions, layers, and/or parts, the elements, components, regions, and/or parts are not limited by the terms. The terms are only used to distinguish one element, component, region, layer, or part from another element, component, region, layer, or part. Therefore, a first “element”, “component”, “region”, “layer”, or “part” discussed below may be referred to as a second element, component, region, layer, or part without departing from the teachings herein.

The terms used herein are only for the purpose of describing specific embodiments and are not limiting. As used herein, unless the content clearly indicates otherwise, the singular forms “a”, “one”, and “the” are intended to include plural forms, including “at least one”. “Or” represents “and/or”. As used herein, the term “and/or” includes any and all combinations of one or more of the relevant listed items. It should also be understood that when used in the specification, the terms “containing” and/or “including” designate the presence of the feature, the region, the entirety, the step, the operation, the element, and/or the component, but do not exclude the presence or the addition of one or more other features, regions, entireties, steps, operations, elements, components, and/or combinations thereof.

In addition, relative terms such as “lower” or “bottom” and “upper” or “top” may be used herein to describe the relationship between an element and another element, as shown in the drawings. It should be understood that the relative terms are intended to include different orientations of a device in addition to the orientation shown in the drawings. For example, if the device in a drawing is flipped, an element described as being on the “lower” side of other elements will be oriented on the “upper” side of the other elements. Therefore, the exemplary term “lower” may include the orientations of “lower” and “upper”, depending on the specific orientation of the drawing. Similarly, if the device in a drawing is flipped, an element described as being “under” or “below” other elements will be oriented “above” the other elements. Therefore, the exemplary term “under” or “below” may include the orientations of above and below.

Unless otherwise defined, all terms (including technical and scientific terms) used herein have the same meaning as commonly understood by persons skilled in the art of the disclosure. It will be further understood that terms such as those defined in commonly used dictionaries should be interpreted as having meanings consistent with the meanings in the related art and the context of the disclosure, and will not be interpreted as having idealized or overly formal meanings unless explicitly defined herein.

The exemplary embodiments are described herein with reference to cross-sectional views that are schematic views of idealized embodiments. Therefore, changes in shapes of illustration as a result of, for example, manufacturing technology and/or tolerances may be expected. Therefore, the embodiments described herein should not be interpreted as being limited to the specific shapes of regions as shown herein, but include, for example, shape deviations caused by manufacturing. For example, a region that is shown or described as flat may generally have rough and/or non-linear features. In addition, an acute angle shown may be rounded. Therefore, the regions shown in the drawings are schematic in nature, and the shapes thereof are not intended to show the precise shapes of the regions and are not intended to limit the scope of the claims.

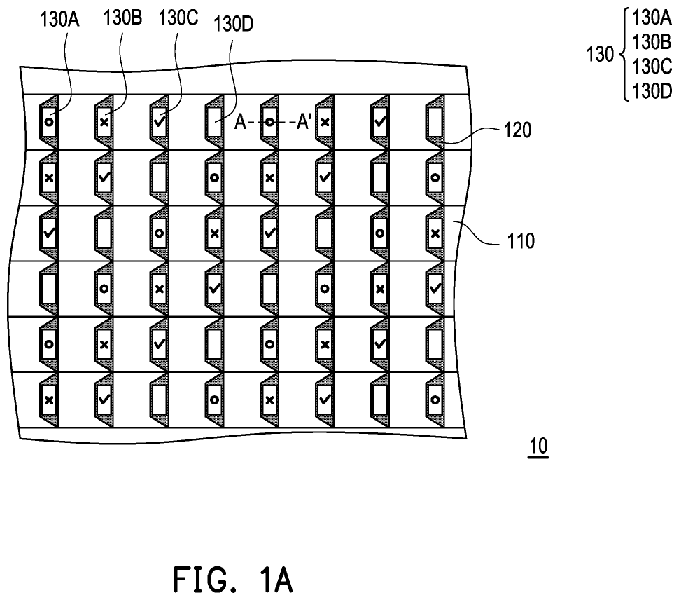

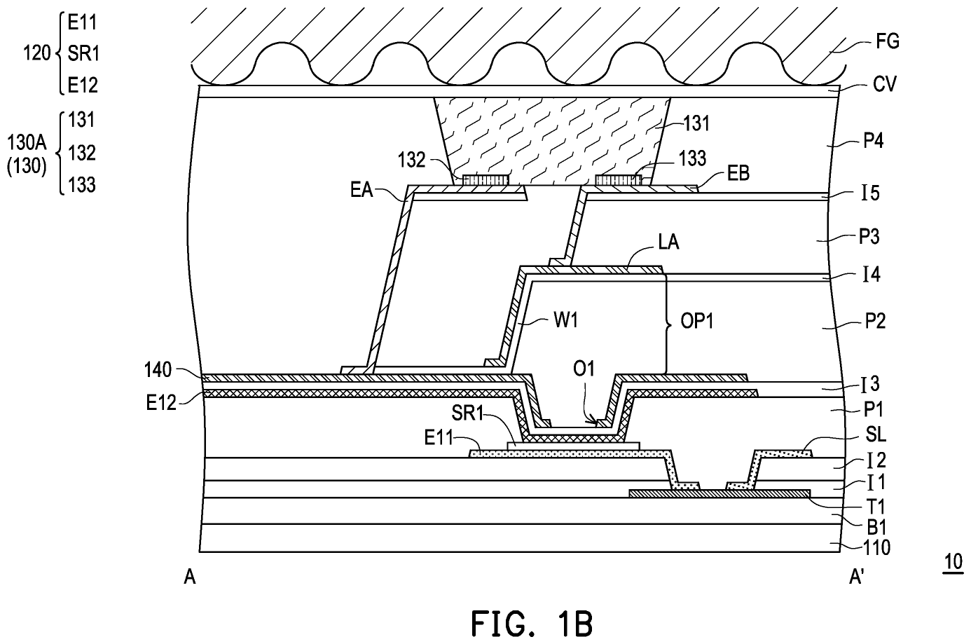

FIG. 1A is a schematic partial top view of a sensing device 10 according to an embodiment of the disclosure. FIG. 1B is a schematic cross-sectional view taken along a cross-sectional line A-A′ of FIG. 1A. In order to simplify the expression of the drawings, FIG. 1A schematically illustrates a first substrate 110, a sensing element 120, and a light-emitting element 130, and other components and film layers are omitted.

Please refer to FIG. 1A and FIG. 1B. The sensing device 10 includes the first substrate 110; the first sensing element 120, located on the first substrate 110; the light-emitting element 130, located on the first sensing element 120; and a light-shielding layer 140, located between the light-emitting element 130 and the first sensing element 120, and electrically connected to the light-emitting element 130.

In the sensing device 10 of an embodiment of the disclosure, by enabling the light-shielding layer 140 of the first sensing element 120 to serve as a signal line for the light-emitting element 130 at the same time, the sensing device 10 can have a simplified integrated structure. Hereinafter, in conjunction with FIG. 1A and FIG. 1B, the implementation of various elements of the sensing device 10 will continue to be described, but the disclosure is not limited thereto.

In the embodiment, the first substrate 110 may be a transparent substrate or an opaque substrate, and the material thereof may be ceramics, quartz, glass, polymer, or other suitable materials, but not limited thereto. Various film layers for forming the first sensing element 120, the light-emitting element 130, the light-shielding layer 140, other signal lines, switching elements, and storage capacitors, etc. may be disposed on the first substrate 110.

In the embodiment, the first sensing element 120 may be a visible light sensing element, such as a fingerprint sensing element that senses visible light, but not limited thereto. For example, the first sensing element 120 may include an electrode E11, a sensing layer SR1, and an electrode E12, wherein the electrode E11 may be located between the first substrate 110 and the sensing layer SR1, and the sensing layer SR1 may be located between the electrode E11 and the electrode E12. In some embodiments, the first sensing element 120 may be an invisible light sensing element, such as a fingerprint sensing element that senses infrared (IR) light.

For example, the material of the electrode E11 may be molybdenum, aluminum, titanium, copper, gold, silver, other conductive materials, or an alloy combination or a stack of two or more of the above materials. The material of the sensing layer SR1 may be silicon-rich oxide (SRO), silicon-rich oxide doped with germanium, or other suitable materials. The material of the electrode E12 is preferably a transparent conductive material, such as indium tin oxide, indium zinc oxide, aluminum tin oxide, aluminum zinc oxide, indium gallium zinc oxide, other suitable oxides, or a stacking layer of at least two of the above.

In some embodiments, the sensing device 10 may further include a flat layer P1, and the flat layer P1 may be disposed between the electrode E11, the sensing layer SR1, and the electrode E12 of the first sensing element 120. The material of the flat layer P1 may include an organic material, such as an acrylic material, a siloxane material, a polyimide material, an epoxy material, or a stacking layer of the above materials, but not limited thereto, and a flat layer described later may also have the same or similar material as the flat layer P1.

In some embodiments, the sensing device 10 may further include a switching element T1 located between the first sensing element 120 and the first substrate 110. The switching element T1 may be electrically connected to the electrode E11 of the first sensing element 120 and a signal line SL. When the switching element T1 is turned on, a signal from the signal line

SL may be transmitted to the electrode E11 of the first sensing element 120. In some embodiments, the sensing device 10 may further include a buffer layer B1. The buffer layer B1 may be disposed between the switching element T1 and the first substrate 110 to prevent impurities in the first substrate 110 from migrating into the switching element T1.

In some embodiments, the sensing device 10 may further include insulating layers I1 and 12. The insulating layers I1 and I2 may be disposed between the switching element T1 and the electrode E11 of the first sensing element 120 and between the switching element T1 and the signal line SL to prevent unnecessary electrical connection. The materials of the insulating layers I1 and I2 may include transparent insulating materials, such as silicon oxide, silicon nitride, silicon oxynitride, a stacking layer of the above materials, or other suitable materials, and an insulating layer described later may also have the same or similar material as the insulating layers I1 and I2. In some embodiments, the sensing device 10 may further include a driving circuit, such as a driving element, a power supply line, a driving signal line, a timing signal line, and a detection signal line, disposed between the first sensing element 120 and the first substrate 110.

In the embodiment, the light-shielding layer 140 may be disposed on the first sensing element 120, the light-shielding layer 140 has an opening O1, and an orthographic projection of the opening O1 on the first substrate 110 may completely overlap with an orthographic projection of the sensing layer SR1 on the first substrate 110, so as to regulate a light-receiving range and a light-receiving amount of the sensing layer SR1. The material of the light-shielding layer 140 may include a material such as metal, metal oxide, metal oxynitride, black resin, or graphite, or a stack of the above materials, but not limited thereto. In some embodiments, the sensing device 10 may further include an insulating layer I3. The insulating layer I3 may be disposed between the electrode E12 of the first sensing element 120 and the light-shielding layer 140 to prevent unnecessary electrical connection.

In some embodiments, the sensing device 10 may further include a light angle control layer LA, a flat layer P2, and an insulating layer I4, wherein the light angle control layer LA is located on the light-shielding layer 140, the flat layer P2 and the insulating layer I4 may be disposed between the light-shielding layer 140 and the light angle control layer LA, and the orthographic projection of the sensing layer SR1 of the first sensing element 120 on the first substrate 110 may completely overlap with an orthographic projection of the light angle control layer LA on the first substrate 110 or at least the orthographic projection of the opening 01 of the light-shielding layer 140 on the first substrate 110 completely overlaps with the orthographic projection of the light angle control layer LA on the first substrate 110. The light angle control layer LA may also extend toward the first sensing element 120 along a side wall W1 of the insulating layer I4, so that the light angle control layer LA can block light rays from directly above and the upper left of the first sensing element 120, and light rays reflected by a finger FG can only enter the sensing layer SR1 of the first sensing element 120 from a lateral light-transmitting opening OP1 in the flat layer P2 and the insulating layer I4 between the light angle control layer LA and the light-shielding layer 140. In this way, only light with a large oblique angle can enter the sensing layer SR1 through the openings OP1 and O1. Experiments have confirmed that such a design can effectively improve the sensing effect of the first sensing element 120.

The light-emitting element 130 may include a light-emitting body 131, a first pad 132, and a second pad 133. In the embodiment, the first pad 132 and the second pad 133 of the light-emitting element 130 are disposed on the same side of the light-emitting body 131. For example, the light-emitting element 130 may be a horizontal micro light-emitting diode, but not limited thereto. In some embodiments, the light-emitting element 130 may be a vertical micro light-emitting diode. The light-emitting element 130 may be manufactured on a growth substrate, and then transferred onto the first substrate 110 through a mass transfer process. The first pad 132 may serve as or be electrically connected to an anode of the light-emitting element 130, and the second pad 133 may serve as or be electrically connected to a cathode of the light-emitting element 130. The light-emitting body 131 may include, for example, a stacking layer of doped and undoped semiconductor materials. The materials of the first pad 132 and the second pad 133 may include, for example, metal materials, alloys, metal nitrides, metal oxides, metal oxynitrides, stacking layers of the above materials, or other suitable materials.

In the embodiment, the light-shielding layer 140 may be electrically connected to the first pad 132 of the light-emitting element 130, so that the light-shielding layer 140 can also serve as a signal line for transmitting a signal for the light-emitting element 130, so as to simplify the integrated structure of the first sensing element 120 and the light-emitting element 130 in the sensing device 10. In addition, since the light-emitting element 130 serving as a light source is disposed above the first sensing element 120, there is no need to reserve an opening area required for a light path of the light-emitting element 130 between the first sensing elements 120, so the configuration density of the first sensing elements 120 can be improved.

In some embodiments, the light angle control layer LA may also be electrically connected to the second pad 133 of the light-emitting element 130, so that the light angle control layer LA can also act as a signal line for the light-emitting element 130, thereby simplifying the integrated structure of the first sensing element 120 and the light-emitting element 130. For example, in the embodiments, the sensing device 10 may further include electrodes EA and EB, a flat layer P3, and an insulating layer I5, wherein the flat layer P3 and the insulating layer IS may be located between the electrode EB and the light angle control layer LA, the electrode EA may be electrically connected to the first pad 132 of the light-emitting element 130 and the light-shielding layer 140, and the electrode EB may be electrically connected to the second pad 133 of the light-emitting element 130 and the light angle control layer LA, but not limited thereto. In other embodiments, the electrode EA may be electrically connected to the first pad 132 and the light angle control layer LA, and the electrode EB may be electrically connected to the second pad 133 and the light-shielding layer 140.

For example, the material of the light angle control layer LA may be molybdenum, aluminum, titanium, copper, gold, silver, other conductive materials, or an alloy combination or a stack of two or more of the above materials. The materials of the electrodes EA and EB may be transparent conductive materials, such as indium tin oxide, indium zinc oxide, aluminum tin oxide, aluminum zinc oxide, indium gallium zinc oxide, other suitable oxides, or a stacking layer of at least two of the above, but not limited thereto.

In some embodiments, the first pads 132 of different light-emitting elements 130 may be electrically connected to different light-shielding layers 140, and the light-shielding layers 140 may also be electrically connected to a system voltage through different switching elements. In this way, whether the signals of the first pads 132 of different light-emitting elements 130 are received or not or voltage levels thereof can be individually controlled. In addition, the light angle control layers LA electrically connected to the second pads 133 of the light-emitting elements 130 may be electrically connected to each other or have the same voltage level. In other words, the light angle control layer LA can also be used as a common electrode of the sensing device 10.

In the embodiment, the orthographic projection of the sensing layer SR1 of the first sensing element 120 on the first substrate 110 may completely overlap with an orthographic projection of the light-emitting element 130 on the first substrate 110. In this way, areas occupied by the first sensing element 120 and the light-emitting element 130 on the first substrate 110, that is, orthographic projection areas of the first sensing element 120 and the light-emitting element 130 on the first substrate 110 can be greatly reduced, so that a greater number of sensing elements and light-emitting elements can be disposed on the first substrate 110.

Please refer to FIG. 1A. In some embodiments, a stacking structure of the first sensing elements 120 and the light-emitting elements 130 may be arranged on the first substrate 110 in the form of an array, and the light-emitting elements 130 may all emit visible light. For example, the light-emitting elements 130 may include light-emitting elements 130A, 130B, 130C, and 130D, and light colors of the light-emitting elements 130A, 130B, 130C, and 130D may be different. For example, the light-emitting element 130A may emit red light, the light-emitting element 130B may emit green light, the light-emitting element 130C may emit blue light, and the light-emitting element 130D may emit white light. In this way, the light-emitting elements 130A, 130B, 130C, and 130D can also respectively constitute sub-pixels of a display panel, so that the sensing device 10 can also provide the function of image display. In some embodiments, the light-emitting elements 130A, 130B, and 130C may emit blue light, the light-emitting element 130D may emit white light, and any two of the light-emitting elements 130A, 130B, and 130C may respectively convert blue light into red light and green light by a color conversion layer. In other words, the visible light emitted by the light-emitting elements 130A, 130B, 130C, and 130D may only include two color lights.

Please refer to FIG. 1B at the same time. The sensing device 10 may further include a cover plate CV and a flat layer P4, wherein the cover plate CV may be disposed on the light-emitting element 130, and the flat layer P4 may be located between the cover plate CV and the insulating layer I5. When the finger FG approaches the cover plate CV, light (for example, light emitted by the light-emitting element 130B) from the right side of the light-emitting element 130A may be reflected by the finger FG to the first sensing element 120 below the light-emitting element 130A.

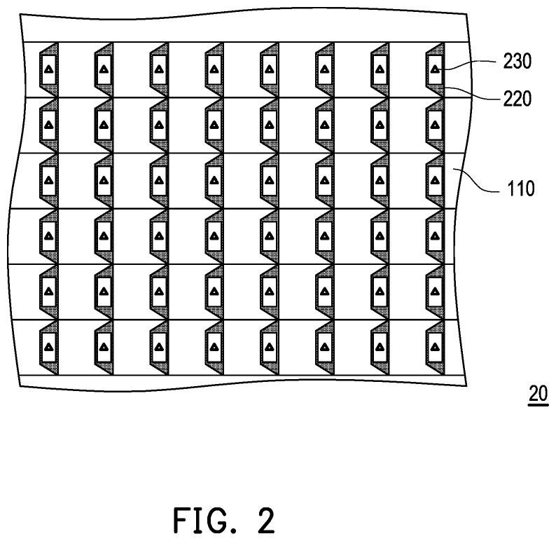

Hereinafter, other embodiments of the disclosure will be described with reference to FIG. 2 to FIG. 5B, and the reference numerals and the related content of the embodiment of FIG. 1A and FIG. 1B will continue to be used, wherein the same reference numerals are adopted to represent the same or similar elements, and the description of the same technical content is omitted. For the description of the omitted part, reference may be made to the embodiment of FIG. 1A and FIG. 1B, which will not be repeated in the following description.

FIG. 2 is a schematic partial top view of a sensing device 20 according to an embodiment of the disclosure. In the embodiment, the sensing device 20 may include a first substrate 110, a first sensing element 220, and a light-emitting element 230, and a stacking structure of the first sensing elements 220 and the light-emitting elements 230 may be arranged on the first substrate 110 in the form of an array.

Compared with the sensing device 10 shown in FIG. 1A and FIG. 1B, the sensing device 20 shown in FIG. 2 is different in that the light-emitting element 230 of the sensing device 20 emits invisible light, such as infrared, and the first sensing element 220 is an invisible light sensing element, such as an infrared sensing element. For example, the first sensing element 220 may be a fingerprint sensing element capable of sensing infrared, but not limited thereto. In some embodiments, the first sensing element 220 may be an organic photodiode.

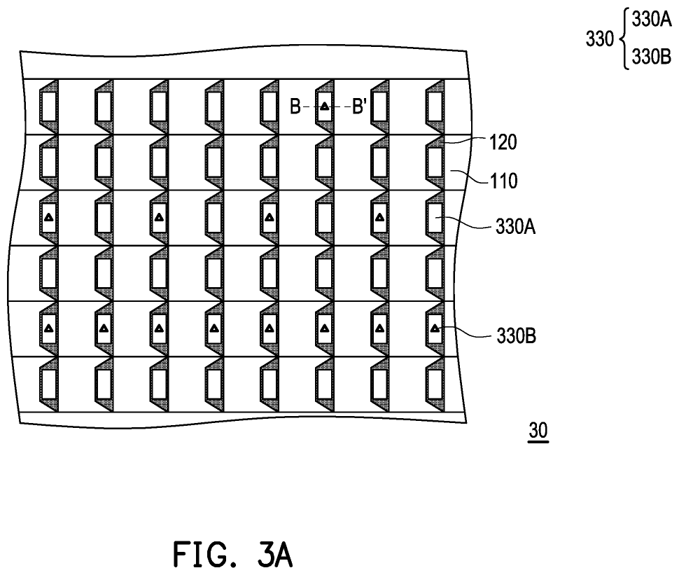

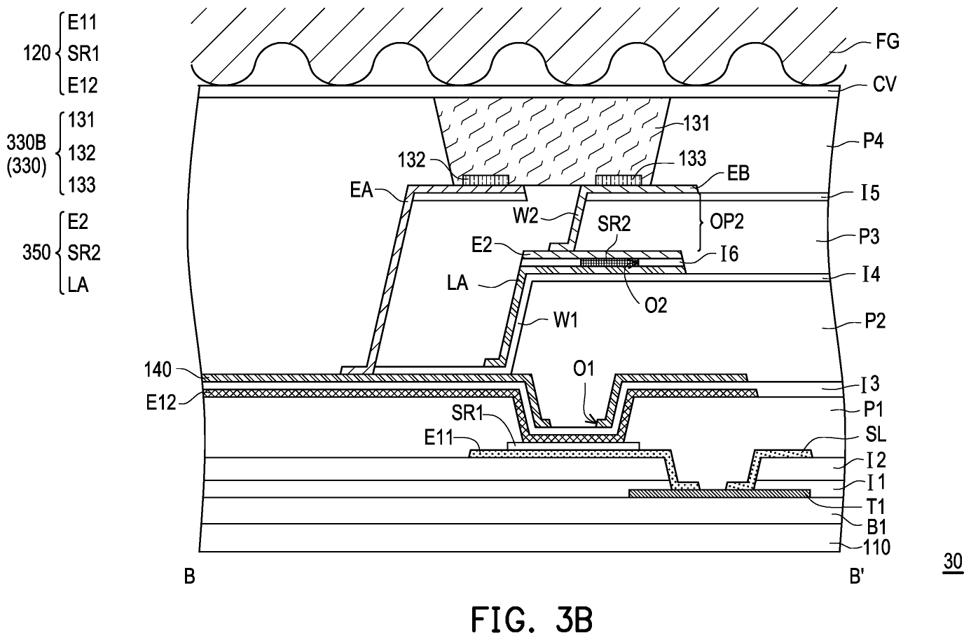

FIG. 3A is a schematic partial top view of a sensing device 30 according to an embodiment of the disclosure. FIG. 3B is a schematic cross-sectional view taken along a cross-sectional line B-B′ of FIG. 3A. In the embodiment, the sensing device 30 may include a first substrate 110, a first sensing element 120, a light-emitting element 330, a light-shielding layer 140, a light angle control layer LA, a switching element T1, electrodes EA and EB, a signal line SL, flat layers P1 to P4, insulating layers I1 to I5, a buffer layer B1, and a cover plate CV.

Compared with the sensing device 10 shown in FIG. 1A and FIG. 1B, the sensing device 30 shown in FIG. 3A and FIG. 3B is different in that the light-emitting elements 330 of the sensing device 30 may include light-emitting elements 330A and 330B, the light-emitting element 330A may emit visible light, and the light-emitting element 330B may emit invisible light. In addition, the sensing device 30 may further include a second sensing element 350, and the second sensing element 350 may partially or completely overlap with the first sensing element 120.

In the embodiment, the arrangement of the light-emitting elements 330A and 330B is not particularly limited, and the arrangement of the light-emitting elements 330A and 330B may be determined according to the amount of light required by the first sensing element 120 and the second sensing element 350. For example, please refer to FIG. 3A. When the fifth row of the sensing device 30 is designed to perform anti-counterfeiting in vivo, an entire row of the light-emitting elements 330B may be disposed in the fifth row to increase the amount of invisible light. The light-emitting element 330B may, for example, emit infrared. At the same time, the second sensing element 350 may be designed to be an invisible light sensing element, such as an infrared sensing element, so that the second sensing element 350 in the fifth row is mainly used to capture a vein image in conjunction with the light-emitting element 330B, so as to implement anti-counterfeiting in vivo.

In the embodiment, the second sensing element 350 may be located between the light-shielding layer 140 and the light-emitting element 330, and the second sensing element 350 may include a light angle control layer LA, a sensing layer SR2 and an electrode E2, wherein the light angle control layer LA may be used as an electrode of the second sensing element 350, and the sensing layer SR2 may be located between the light angle control layer LA and another electrode E2 and in an opening 02 of an insulating layer I6. A second pad 133 of the light-emitting element 330 may be electrically connected to the electrode E2 through the electrode EB, and the electrode E2 can also be used as a common electrode of the sensing device 30.

In the embodiment, an orthographic projection of the sensing layer SR2 of the second sensing element 350 on the first substrate 110 may partially overlap with an orthographic projection of a sensing layer SR1 of the first sensing element 120 on the first substrate 110, but not limited thereto. In some embodiments, the orthographic projection of the sensing layer SR2 of the second sensing element 350 on the first substrate 110 may completely overlap with the orthographic projection of the sensing layer SR1 of the first sensing element 120 on the first substrate 110.

In the embodiment, since a side wall W2 of the electrode EB extends toward the second sensing element 350 to be electrically connected to the electrode E2, the electrode EB can also block light rays from directly above and the upper left of the sensing layer SR2 of the second sensing element 350, and light rays reflected by a finger FG can only enter the sensing layer SR2 from a lateral light-transmitting opening OP2 in the flat layer P3 and the insulating layer I5 between the electrode EB and the electrode E2. In other words, the electrode EB can also act as a light angle control layer of the second sensing element 350, so that only light with a large oblique angle can enter the sensing layer SR2 through the opening OP2.

In the embodiment, the material of the sensing layer SR2 may be silicon-rich oxide doped with germanium or other suitable materials. The materials of the electrodes E2 and EA are preferably transparent conductive materials, such as indium tin oxide, indium zinc oxide, aluminum tin oxide, aluminum zinc oxide, indium gallium zinc oxide, other suitable oxides, or a stacking layer of at least two of the above. The material of the electrode EB may be molybdenum, aluminum, titanium, copper, gold, silver, other conductive materials, or an alloy combination or a stack of two or more of the above materials.

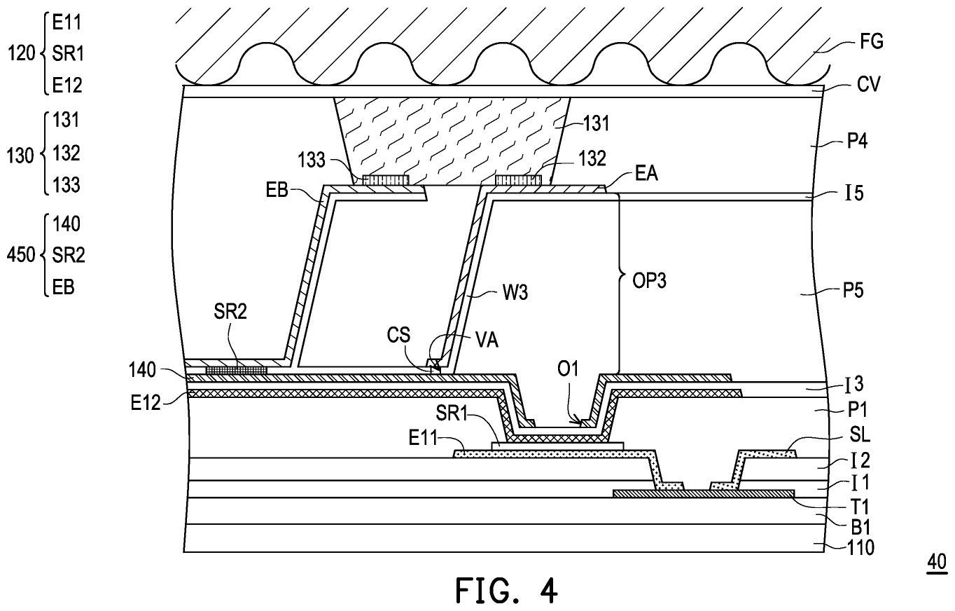

FIG. 4 is a schematic partial cross-sectional view of a sensing device 40 according to an embodiment of the disclosure. In the embodiment, the sensing device 40 may include a first substrate 110, a first sensing element 120, a light-emitting element 130, a light-shielding layer 140, a switching element T1, electrodes EA and EB, a signal line SL, flat layers P1, P4, and P5, insulating layers I1 to I3 and I5, a buffer layer B1, and a cover plate CV.

Compared with the sensing device 10 shown in FIG. lA and FIG. 1B, the sensing device 40 shown in FIG. 4 is different in that the sensing device 40 does not need to be provided with a light angle control layer LA; the configuration positions of an electrode EA, an electrode EB, and a first pad 132 and a second pad 133 of the light-emitting element 130 relative to the first sensing element 120 are different; an orthographic projection of a sensing layer SR1 of the first sensing element 120 on the first substrate 110 partially overlaps with an orthographic projection of the light-emitting element 130 on the first substrate 110; and the sensing device 40 further includes a second sensing element 450, and the second sensing element 450 does not overlap with the first sensing element 120.

For example, in the embodiment, the flat layer P5 of the sensing device 40 may replace the light angle control layer LA, the flat layers P2 and P3, and the insulating layer I4 of the sensing device 10, and the flat layer P5 may be disposed between the insulating layer I5 and the light-shielding layer 140. In addition, the configuration positions of the electrode EA and the electrode EB relative to the first sensing element 120 may be interchanged, the configuration positions of the first pad 132 and the second pad 133 relative to the first sensing element 120 may be interchanged, and the electrode EA may be electrically connected to the light-shielding layer 140 through a conductive structure CS in a via VA of the insulating layer I5, so that the first pad 132 of the light-emitting element 130 can be electrically connected to the light-shielding layer 140 through the electrode EA and the conductive structure CS. In some embodiments, the light-shielding layer 140 may also be electrically connected to a system voltage. In other words, the light-shielding layer 140 may also serve as a power supply line of the sensing device 40, so that the first pad 132 of the light-emitting element 130 can have a voltage level controlled by the system voltage.

In the embodiment, the orthographic projection of the sensing layer SR1 of the first sensing element 120 on the first substrate 110 may completely overlap with an orthographic projection of the electrode EA on the first substrate 110, and the electrode EA may also extend toward the first sensing element 120 along a side wall W3 of the insulating layer I5, so that the electrode EA can block light rays from directly above and the upper left of the first sensing element 120, and light rays reflected by a finger FG can only enter the first sensing element 120 from a lateral light-transmitting opening OP3 in the flat layer P5 and the insulating layer I5 between the electrode EA and the light-shielding layer 140. In other words, the electrode EA can also act as a light angle control layer of the first sensing element 120, so that only light with a large oblique angle can enter the sensing layer SR1 of the first sensing element 120 through the openings OP3 and O1.

In the embodiment, the second sensing element 450 may include the light-shielding layer 140, the sensing layer SR2, and the electrode EB, wherein the sensing layer SR2 is located between the light-shielding layer 140 and the electrode EB, and the light-shielding layer 140 and the electrode EB may be used as two electrodes of the second sensing element 450. The electrode EB of the second sensing element 450 is electrically connected to the second pad 133 of the light-emitting element 130. In some embodiments, the electrode EB may also be electrically connected to a common electrode of the sensing device 40. In the embodiment, an orthographic projection of the sensing layer SR2 of the second sensing element 450 on the first substrate 110 may be outside the orthographic projection of the sensing layer SR1 of the first sensing element 120 or the light-emitting element 130 on the first substrate 110. In other words, the sensing layer SR2 of the second sensing element 450 may not overlap with the sensing layer SR1 of the first sensing element 120 or the light-emitting element 130. In this way, the second sensing element 450 can, for example, sense light rays from directly above.

In the embodiment, the material of the electrode EA is preferably molybdenum, aluminum, titanium, copper, gold, silver, other conductive materials, or an alloy combination or a stack of two or more of the above materials, and the material of the electrode EB is preferably a transparent conductive material, such as indium tin oxide, indium zinc oxide, aluminum tin oxide, aluminum zinc oxide, indium gallium zinc oxide, other suitable oxides, or a stacking layer of at least two of the above.

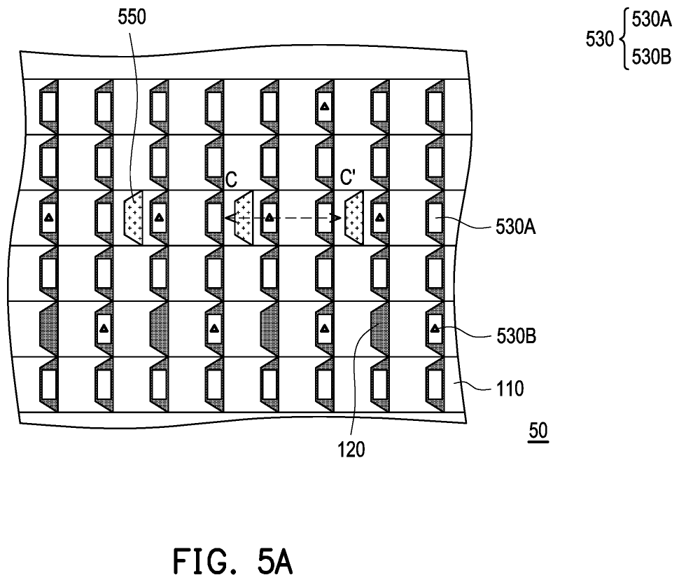

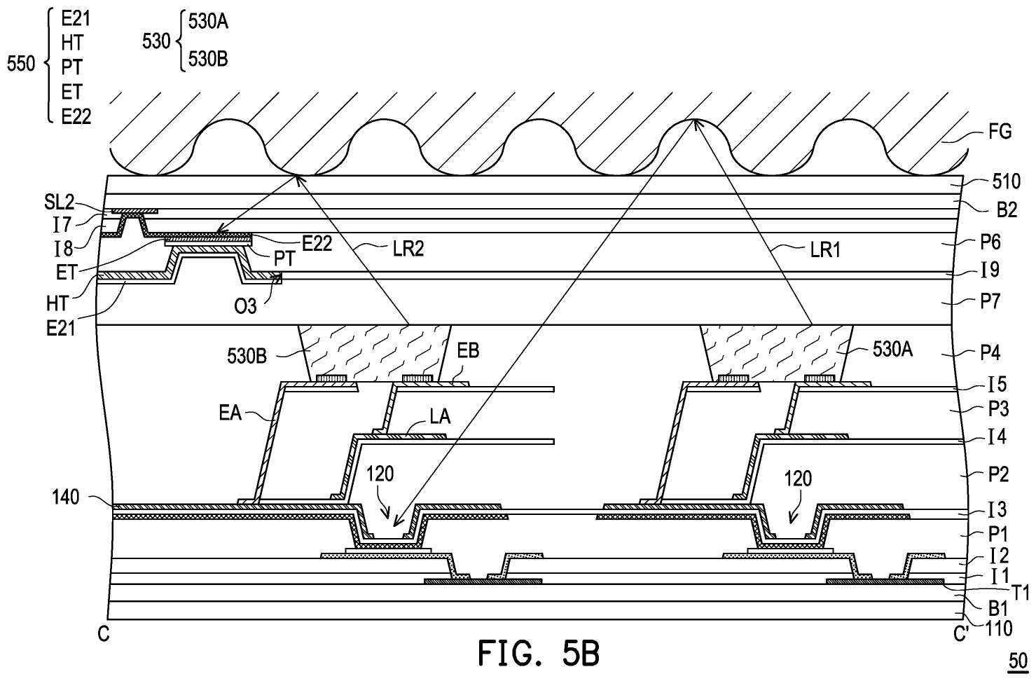

FIG. 5A is a schematic partial top view of a sensing device 50 according to an embodiment of the disclosure. FIG. 5B is a schematic cross-sectional view taken along a cross-sectional line C-C′ of FIG. 5A. In the embodiment, the sensing device 50 may include a first substrate 110, a first sensing element 120, a light-emitting element 530, a light-shielding layer 140, a light angle control layer LA, a switching element T1, electrodes EA and EB, flat layers P1 to P4, insulating layers I1 to I5, and a buffer layer B1.

Compared with the sensing device 10 shown in FIG. 1A and FIG. 1B, the sensing device 50 shown in FIG. 5A and FIG. 5B is different in that the sensing device 50 further includes a second substrate 510 and a second sensing element 550, wherein the second substrate 510 is located on the light-emitting element 530, the second sensing element 550 is disposed on the second substrate 510, the first sensing element 120, the light-emitting element 530, and the second sensing element 550 are located between the first substrate 110 and the second substrate 510, and the first sensing element 120 and the second sensing element 550 may be respectively located on different sides or opposite sides of the light-emitting element 530.

In the embodiment, the second sensing element 550 may be located between the second substrate 510 and the light-emitting element 530, and by combining the first substrate 110 with the first sensing element 120 and the light-emitting element 530 with the second sensing element The second substrate 510 of the device 550 is paired to complete the fabrication of the sensing device 50. In this way, the dual-substrate design of the sensing device 50 may help improve the reliability of the sensing device and the light-emitting element.

In the embodiment, the second sensing element 550 may be an invisible light sensing element, such as an organic photodiode (OPD), for sensing blood oxygen concentration or heartbeat, capturing a vein image for anti-counterfeiting in vivo, or capturing a fingerprint image.

For example, the second sensing element 550 may include an electrode E21, a hole transport layer HT, a photosensitive layer PT, an electron transport layer ET, and an electrode E22, wherein the electron transport layer ET, the photosensitive layer PT, and the hole transport layer HT are located between the electrode E21 and the electrode E22, and the electron transport layer ET may be located between the photosensitive layer PT and the second substrate 510, but not limited thereto. In some embodiments, the hole transport layer HT may be located between the photosensitive layer PT and the second substrate 510. In addition, in some embodiments, the first sensing element 120 and the second sensing element 550 may both be invisible light sensing elements, and sensing wavelength ranges of the first sensing element 120 and the second sensing element 550 may be different.

For example, the electrode E21 may be an opaque conductive material, such as a silver layer or an aluminum layer. The hole transport layer HT may include poly(3,4-ethylene-dioxythiophene:polystyrene sulfonate) (PEDOT:PSS) or a high work function metal oxide, such as MoO₃. The photosensitive layer PT may include a photosensitive polymer that absorbs in an infrared region and/or a near-infrared (NIR) region, such as poly(3-hexylthiophene):[6,6]-phenyl-C61-butyric acid methyl ester (P3HT:PCBM) or poly-(diketopyrrole-terthiophene):[6,6]-phenyl-C61-butyric acid methyl ester (PDPP3T-PCBM). The electron transport layer ET may include zinc oxide (ZnO) or aluminum zinc oxide (AZO), and the material of the electrode E22 may be a transparent conductive material, such as indium tin oxide (ITO).

In some embodiments, the sensing device 50 may further include flat layers P6 and P7 and an insulating layer I9, wherein the hole transport layer HT may be located in an opening O3 of the insulating layer I9, the flat layer P6 may be located between the hole transport layer HT and the insulating layer I9 and the second substrate 510, and the flat layer P7 may be located between the electrode E21 and the insulating layer I9 and the light-emitting element 530.

In some embodiments, the sensing device 50 may further include a signal line SL2 located between the second sensing element 550 and the second substrate 510. The signal line SL2 may be electrically connected to the electrode E22 of the second sensing element 550, and the signal line SL2 may contain, for example, a metal material with a relatively low resistance value. When the electrode E22 containing a transparent conductive material has a relatively large resistance value, the signal line SL2 helps to improve the signal transmission rate to the electrode E22. In some embodiments, the sensing device 50 may further include a buffer layer B2, and the buffer layer B2 may be disposed between the signal line SL2 and the second substrate 510. In some embodiments, the sensing device 50 may further include insulating layers I7 and I8, and the insulating layers I7 and I8 may be disposed between the signal line SL2 and the electrode E22 of the second sensing element 550 to prevent unnecessary electrical connection. In some embodiments, the sensing device 50 may further include a driving circuit, such as a driving element, a power supply line, a driving signal line, a timing signal line, and a detection signal line, disposed between the second sensing element 550 and the second substrate 510.

In the embodiment, the light-emitting element 530 of the sensing device 50 may include light-emitting elements 530A and 530B, the light-emitting element 530A may emit visible light, and the light-emitting element 530B may emit invisible light, but not limited thereto. In some embodiments, the light-emitting elements 530A and 530B may emit visible light with different colors, such as red light, green light, blue light, or white light.

In the embodiment, the arrangement of the light-emitting elements 530A and 530B is not particularly limited, and the arrangement of the light-emitting elements 530A and 530B may be determined according to the amount of light required by the first sensing element 120 and the second sensing element 550. For example, please refer to FIG. 5A. The light-emitting elements 530A and 530B located in the third row of the sensing device 50 may be alternately arranged. In addition, certain first sensing elements 120 in the fifth row of the sensing device 50 may not be provided with any light-emitting element 530A that emits visible light. In some embodiments, the second sensing element 550 may be disposed at a required place according to requirements, for example, only disposed in the third row of the sensing device 50, and an orthographic projection of the second sensing element 550 on the first substrate 110 may be outside orthographic projections of the light-emitting elements 530A and 530B on the first substrate 110. In this way, please refer to FIG. 5B. When the user touches the glass second substrate 510 with a finger FG to perform sensing, such as fingerprint, vein image, blood oxygen concentration, and heartbeat sensing, a visible light LR1 emitted by the light-emitting element 530A may be reflected by the finger FG to the first sensing element 120 below the light-emitting element 530B, and an invisible light LR2 emitted by the light-emitting element 530B may be reflected by the finger FG to the second sensing element 550, so that the second sensing element 550 may locally provide functions such as fingerprint recognition, anti-counterfeiting in vivo, or blood oxygen concentration sensing in conjunction with the light-emitting element 530B.

In summary, in the sensing device of the disclosure, the light-shielding layer of the sensing element is electrically connected to the light-emitting element, so that the light-shielding layer can serve as the signal line for the light-emitting element at the same time, thereby simplifying the integrated structure of the sensing element and the light-emitting element. In addition, in the sensing device of the disclosure, there is no need to reserve an opening area between the sensing elements, so the configuration density of the sensing elements can be improved. In addition, in the sensing device of the disclosure, the light angle control layer of the sensing element can also serve as the signal line for the light-emitting element at the same time to simplify the integrated structure of the sensing element and the light-emitting element.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A sensing device, comprising:
a first substrate;
a first sensing element, located on the first substrate;
a light-emitting element, located on the first sensing element; and
a light-shielding layer, located between the light-emitting element and the first sensing element, and electrically connected to the light-emitting element.

2. The sensing device according to claim 1, wherein an orthographic projection of the first sensing element on the first substrate at least partially overlaps with an orthographic projection of the light-emitting element on the first substrate.

3. The sensing device according to claim 1, wherein the light-emitting element emits visible light, and the visible light comprises at least two color lights.

4. The sensing device according to claim 1, wherein the light-emitting element emits invisible light.

5. The sensing device according to claim 1, further comprising: a light angle control layer, located between the light-shielding layer and the light-emitting element, wherein the light-shielding layer and the light angle control layer are respectively electrically connected to two pads of the light-emitting element.

6. The sensing device according to claim 1, further comprising: a second sensing element, located between the light-shielding layer and the light-emitting element.

7. The sensing device according to claim 6, wherein an electrode of the second sensing element is electrically connected to the light-emitting element.

8. The sensing device according to claim 6, wherein an orthographic projection of the second sensing element on the first substrate at least partially overlaps with an orthographic projection of the first sensing element on the first substrate.

9. The sensing device according to claim 6, wherein an orthographic projection of the second sensing element on the first substrate is outside an orthographic projection of the first sensing element on the first substrate.

10. The sensing device according to claim 1, further comprising: a second sensing element, wherein the first sensing element and the second sensing element are located on different sides of the light-emitting element.

11. The sensing device according to claim 10, wherein an orthographic projection of the second sensing element on the first substrate is outside an orthographic projection of the light-emitting element on the first substrate.

12. The sensing device according to claim 10, wherein the second sensing element is an organic photodiode.

13. The sensing device according to claim 1, wherein the first sensing element is a fingerprint sensing element.
